(19) United States
(12) Patent Application Publication
(10) Pub. No.: US 2025/0104961 A1
(43) Pub. Date: Mar. 27, 2025

(54) METHOD FOR OPERATING A MULTI-BEAM PARTICLE MICROSCOPE, COMPUTER PROGRAM PRODUCT AND MULTI-BEAM PARTICLE MICROSCOPE

(71) Applicant: Carl Zeiss MultiSEM GmbH, Oberkochen (DE)

(72) Inventors: Michael Behnke, Eislingen (DE); Stefan Schubert, Oberkochen (DE)

(21) Appl. No.: 18/975,361

(22) Filed: Dec. 10, 2024

Related U.S. Application Data
(63) Continuation of application No. PCT/EP2023/025240, filed on May 24, 2023.

(30) Foreign Application Priority Data
Jun. 14, 2022 (DE) 10 2022 114 923.4

(51) Int. Cl. H01J 37/26; H01J 37/28

(52) U.S. Cl. CPC H01J 37/265; H01J 37/28

(57) ABSTRACT

A method for operating a multi-beam particle microscope in an inspection mode of operation and an associated multi-beam particle microscope are disclosed, wherein a detection unit comprises an image generation detection region with fixedly assigned detection channels and an adjustment detection region with additional detection channels. The fixedly assigned detection channels and the additional detection channels are in the same detection plane. Based on signals obtained via the additional detection channels, it is possible to correct an incidence position of the secondary beams on the detection unit in real time, to be precise independently of the specific structure of the detection unit.

### CROSS-REFERENCE TO RELATED APPLICATIONS

The present application is a continuation of, and claims benefit under 35 USC 120 to, international application No. PCT/EP2023/025240, filed May 24, 2023, which claims benefit under 35 USC 119 of German Application No. 10 2022 114 923.4, filed Jun. 14, 2022. The entire disclosure of each of these applications is incorporated by reference herein.

### FIELD

The disclosure relates to a method for operating a multi-beam particle microscope, to an associated computer program product and to a multi-beam particle microscope.

### BACKGROUND

With the continuous development of ever smaller and ever more complex microstructures such as semiconductor components, there is a desire to further develop and optimize planar production techniques and inspection systems for producing and inspecting small dimensions of the microstructures. By way of example, the development and production of the semiconductor components can involve monitoring of the design of test wafers, and the planar production techniques can involve process optimization for a reliable production with a high throughput. Moreover, there have been recent demands for an analysis of semiconductor wafers for reverse engineering and for a customer-specific, individual configuration of semiconductor components. Therefore, there is a desire for an inspection mechanism which can be used with a high throughput for examining the microstructures on wafers with great accuracy.

Typical silicon wafers used in the production of semiconductor components have diameters of up to 300 millimeters (mm). Each wafer is divided into 30 to 60 repeating regions (“dies”) with a size of up to 800 square millimeters (mm²). A semiconductor apparatus comprises a plurality of semiconductor structures, which are produced in layers on a surface of the wafer by planar integration techniques. Semiconductor wafers typically have a plane surface on account of the production processes. The structure size of the integrated semiconductor structures in this case extends from a few μm to the critical dimensions (CD) of 5 nanometers (nm), with the structure sizes becoming even smaller in the near future; in future, structure sizes or critical dimensions (CD) are expected to be less than 3 nm, for example 2 nm, or even under 1 nm. In the case of the aforementioned small structure sizes, defects in the size of the critical dimensions is to be identified quickly in a very large area. For several applications, the desired accuracy of a measurement provided by inspection equipment is even higher, for example by a factor of two or one order of magnitude. By way of example, a width of a semiconductor feature is to be measured with an accuracy of below 1 nm, for example 0.3 nm or even less, and a relative position of semiconductor structures is to be determined with an overlay accuracy of below 1 nm, for example 0.3 nm or even less.

The MSEM, a multi-beam scanning electron microscope, is a relatively new development in the field of charged particle systems (charged particle microscopes, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or raster. By way of example, 4 to 10,000 individual electron beams can be provided as primary radiation, with each individual electron beam being separated from an adjacent individual electron beam by a pitch of 1 to 200 micrometres (μm). By way of example, an MSEM has approximately 100 separate individual electron beams (“beamlets”), which are arranged for example in a hexagonal raster, with the individual electron beams being separated by a pitch of approximately 10 μm. The plurality of charged individual particle beams (primary beams) are focused on a surface of a sample to be examined by way of a common objective lens. By way of example, the sample can be a semiconductor wafer which is secured to a wafer holder mounted on a movable stage. During the illumination of the wafer surface with the charged primary individual particle beams, interaction products, for example secondary electrons or backscattered electrons, emanate from the surface of the wafer. Their start points correspond to those locations on the sample on which the plurality of primary individual particle beams are focused in each case. The amount and the energy of the interaction products generally depend on the material composition and the topography of the wafer surface. The interaction products form a plurality of secondary individual particle beams (secondary beams), which are collected by the common objective lens and which are incident on a detector arranged in a detection plane as a result of a projection imaging system of the multi-beam inspection system. The detector comprises a plurality of detection regions, each of which comprises a plurality of detection pixels, and the detector captures an intensity distribution for each of the secondary individual particle beams. An image field of, for example, 100 μm×100 μm is obtained in the process.

Certain known multi-beam electron microscopes comprise a sequence of electrostatic and magnetic elements. At least some of the electrostatic and magnetic elements are adjustable in order to adapt the focus position and the stigmation of the plurality of charged individual particle beams. These multi-beam systems with charged particles moreover comprise at least one cross-over plane of the primary or the secondary charged individual particle beams. Moreover, these systems comprise detection systems to make the adjustment easier. These multi-beam particle microscopes comprise at least one beam deflector (“deflection scanner”) for collective scanning of a region of the sample surface via the plurality of primary individual particle beams in order to obtain an image field of the sample surface. Further details regarding a multi-beam electron microscope and a method for operating same are described in the German patent application with the application Ser. No. 10/202,0206739.2, filed on May 28, 2020, and in the associated patent family documents, the disclosure of which is fully incorporated by reference in this patent application.

An accurate alignment of the secondary individual particle beams when incident on the detector is relevant in order to obtain a high resolution within the scope of a sample inspection, for example a semiconductor sample inspection. It is standard for the alignment of the raster of second individual particle beams to be carried out by virtue of carrying out referencing in relation to a centrally arranged beam in the raster. The latter is aligned or adjusted to the best possible extent in relation to a detection region assigned thereto. This alignment is usually carried out prior to each image recording.

However, it is also possible that an alignment of the second individual particle beams changes in relation to the detection regions of the detection unit while the image is recorded, for example as a result of the occurrence of a drift or due to the sample properties themselves. By way of example, charging effects on the sample may lead to secondary individual beams emanating or starting from the sample being slightly warped and therefore not being incident at the desired reference position on the detection unit. In such cases, it would be desirable to carry out a correction or readjustment in real time.

In this context, DE 10 2015 202 172 B4 proposes the use of a pixelated detection unit in which the detection regions, which are each provided for the detection of a second individual particle beam and assigned to the latter, each have a plurality of detection fields. If the incidence locations of the second individual particle beams on the detector change during an inspection, then the assignment of the detection fields to the detection regions is modified. On the one hand, this procedure restricts the type of used detection units to pixelated detection units and, on the other hand, such an assignment modification is algorithmically quite complex and comparatively slow.

U.S. Pat. No. 10,896,800 B2 avoids the issue of the restriction to the pixelated detector type for image generation by virtue of an additional pixelated detector in the form of a fast CCD camera being used in addition to the non-pixelated detector for the image generation (a combination of a particle detector and a downstream light optical unit with an optical fibre for each detection region). To this end, a beam splitter is provided in the light-detection path; a portion of the light signal is output to the CCD camera. Positions on the CCD camera can be assigned positions of the light when incident on the signal entrance surface of the optical fibres. Using this, it is possible to indirectly detect positional deviations of second individual beams when incident on the detector used for image generation. In general, this allows a fast positional correction in the secondary path of the multi-beam particle microscope. For the correction of the particle optical beam path in the secondary path itself, use is made of quickly controllable electrostatic lenses, electrostatic deflectors and/or electrostatic stigmators. According to U.S. Pat. No. 10,896,800 B2, the light incident on the pixelated additional detector for positional deviation recognition purposes is obtained by beam splitting, which attenuates the original light signal. Moreover, with respect to the detection unit, one is bound to the combination of a particle detection with a light detection as a result of the beam splitting in the light optical system. Additionally, the signal evaluation in the case of the CCD camera with an evaluation of signals from all pixels is algorithmically comparatively complicated.

US 2021/0005423 A1 also discloses a combination of a particle detector and a downstream light optical unit with an optical fibre for each detection region. A beam splitter is provided in the light-detection path; and a portion of the light signal is output to a CCD camera which can be used to identify changes of the locations of the interaction products in a detection plane due to a charging of a sample. Furthermore, US 2021/0005423 A1 discloses a diaphragm which is arranged in the detection system at a position of a cross-over of secondary particle beams. The circular opening of the diaphragm is surrounded in a radial direction by a couple of electrodes which can serve as current detectors. By detecting asymmetries in the currents or charges induced in the electrodes, a decentering of the charged particle beams passing the aperture of the diaphragm can be detected and thus corrected, accordingly.

### SUMMARY

The present disclosure proposes a method for operating a multi-beam particle microscope in an inspection mode, and an associated multi-beam particle microscope, which can allow a relatively simple and universal fast positional correction of the secondary beams when incident on a detection unit.

According to a first aspect, the disclosure provides a method for operating a multi-beam particle microscope in an inspection mode of operation, the method including the following steps:
irradiating an object with a plurality of charged first individual particle beams, wherein each first individual particle beam irradiates a separate individual field region of the object in a scanning fashion;
collecting second individual particle beams which emerge from the object on account of the first individual particle beams or which emanate from the object;
focused projecting of the second individual particle beams onto detection regions of a detection unit in such a way that the second individual particle beams emerging from two different individual field regions are projected onto different detection regions, wherein a detection channel or a predetermined plurality of detection channels is fixedly assigned to each detection region;
reading the fixedly assigned detection channels and generating individual images of each of the individual field regions on the basis of data obtained via signals from each of the detection regions with their respective fixedly assigned detection channel or with their respective fixedly assigned detection channels;
reading additional detection channels from the same detection unit, onto which the second individual particle beams are not projected in targeted fashion and which are not assigned to any detection region, and determining a positional deviation of the second individual particle beams from a reference incidence position when incident on the detection unit on the basis of data obtained via signals from the additional detection channels;
correcting the positional deviation of the second individual particle beams when incident on the detection unit in real time.

The first charged individual particle beams can be, for example, electrons, positrons, muons or ions or other charged particles. The individual field regions of the object that are assigned to each first individual particle beam are raster scanned, for example line by line or column by column. In this case, it can be desirable for the individual field regions to be adjacent to one another or to cover the object or a part thereof in tessellated fashion. The individual field regions are substantially separate from one another, but they can also overlap one another in the marginal regions. In this way, it is possible to obtain an image of the object that is as complete and contiguous as possible. The individual field regions can be embodied in rectangular or square fashion since this is the easiest to realize for the scanning process with the aid of particle radiation. The individual field regions can be arranged as rectangles in different lines one above another so as to result overall in a hexagonal structure. It can be desirable for the number of particle beams to be 3n (n−1)+1, where n is any natural number, in the hexagonal case. Other arrangements of the individual field regions, for example in a square or rectangular raster, are likewise possible.

The second individual particle beams can be backscattered electrons or else secondary electrons. In this case, for analysis purposes it is desirable for the low-energy secondary electrons to be used for image generation. However, it is also possible for mirror ions/mirror electrons to be used as second individual particle beams, that is to say first individual particle beams undergoing reversal directly upstream of or at the object.

According to the disclosure, the second individual particle beams can be projected in focused fashion onto detection regions of a detection unit so that the second individual particle beams emerging or emanating from two different individual field regions are projected onto different detection regions. In this case, each detection region is fixedly assigned a detection channel or a predetermined plurality of detection channels. The fact that a detection region may therefore correspond to a detection channel or else that a detection region may comprise a plurality of detection channels and hence smaller units allows the application of the method basically independently of the type of detection unit. It is not necessary for a detection region per second individual particle beam to be pixelated or subdivided more finely. Instead, the method involves the fixed assignment of a detection channel or a predetermined plurality of detection channels to a respective detection region. Thus, in some embodiments according to the disclosure, there is no change in this assignment as described above in the context of known technology (DE 10 2015 202 172 B4). Overall, the disclosure therefore can simplify the method and it becomes more universally applicable.

According to the disclosure, the detection unit can be additionally modified or extended. In addition to the detection regions used to generate individual images, the detection unit can comprise additional detection channels. The second individual particle beams are not projected onto these additional detection channels in a targeted manner and the detection channels are not assigned to any detection region. Thus, if the second individual particle beams are incident on the detection unit at their respective reference incidence position, no signal, in general, is detected in these additional detection channels. The additional detection channels only detect a signal if at least one of the second individual particle beams, but optionally a plurality of the second individual particle beams, deviate(s) from its/their respective reference incidence position. Consequently, the additional detection channels serve to determine a positional deviation. Such a positional deviation can be recognized as such and optionally also be characterized in more detail. This can help make it possible to correct the positional deviation of the second individual particle beams when incident on the detection unit.

With respect to their structure, the additional detection channels may correspond to the detection channels also used for the normal image generation. However, it is also possible to design the additional detection channels differently. Specific exemplary embodiments will still be discussed in more detail below.

The fixedly assigned detection channels and the additional detection channels can belong to the same detection unit. Therefore, the fixedly assigned detection channels and the additional detection channels can be provided within the same detection plane. In other words, an image detection plane and a positional deviation detection plane are identical according to the present disclosure. This identity enhances the precision with which a positional deviation can be detected.

According to the disclosure, the positional deviation of the second individual particle beams when incident on the detection unit can be corrected in real time. In general, mechanisms in the secondary path of the multi-beam particle microscope usable to this end are already known. Attention is drawn to the fact that, within the scope of a correction in real time, the correction of a positional deviation can be implemented, in particular implemented multiple times, still during the generation of the individual images. Thus, if desired, there can be multiple readjustments or corrections per individual image. As a result, a better resolution overall can be obtained within the scope of a sample inspection.

According to an embodiment of the disclosure, the correction of the positional deviation of the second individual particle beams comprises an adjustment of the particle optical beam path of the second individual particle beams in real time. Alternatively, it would also be possible for the positional deviation to be corrected by a modification of the position of the detection unit itself; however, such a correction would not be implemented in real time.

According to an embodiment of the disclosure, the method furthermore includes the following step: classifying the determined positional deviation and, on the basis thereof, correcting the positional deviation. A positional deviation often relates to the raster of second individual particle beams equally or globally. Classes or types of a positional deviation are for example a global displacement of the second individual particle beams when incident on the detection unit, a global rotation, a magnification of the entire raster or overall anamorphic imaging. In the process, it may be possible to determine merely one class or one type of a global positional deviation, but it is also possible to simultaneously recognize a plurality of the aforementioned types (as a superposition).

According to an embodiment of the disclosure, the correction of the positional deviation comprises a correction of a global displacement of the second individual particle beams when incident on the detection unit. By way of example, a fast deflection system in the second particle optical beam path/secondary path of the multi-beam particle microscope can be used for correction purposes. Solely the type of beam correction in the secondary path has already been described in U.S. Pat. No. 10,896,800 B2, the disclosure of which is incorporated in its entirety by reference into this patent application.

According to an embodiment of the disclosure, the correction of the positional deviation comprises a correction of a global rotation of the second individual particle beams when incident on the detection unit. By way of example, a rotation lens in the second particle optical beam path/secondary path of the multi-beam particle microscope can be used for this global rotation of the raster of second individual particle beams. It can be controlled quickly. It is also possible to use a rotation correction mechanism in the secondary path as are described in a plurality of embodiment variants in the German patent DE 10 2020 125 534 B3, for example. The entirety of the disclosure of DE 10 2020 125 534 B3 is incorporated in the present patent application by reference.

According to an embodiment of the disclosure, the correction of the positional deviation comprises a correction of a magnification of the second individual particle beams in one direction or in two directions when incident on the detection unit. In this case, the two directions may be orthogonal to one another, but this is not mandatory. If a magnification is the same size in both directions, this relates overall to a global enlargement as a positional deviation. For correction purposes, it is once again possible to use a system with fast electrostatic lenses, for example as described in the above-cited U.S. Pat. No. 10,896,800 B2

A magnification of the raster in one direction only corresponds to anamorphic imaging. By way of example, this can be corrected by way of a fast electrostatic stigmator or stigmation system in the secondary path, as likewise has already been described in exemplary fashion in U.S. Pat. No. 10,896,800 B2.

According to an embodiment of the method, the latter comprises the following step: correcting an individual positional deviation of at least one second individual particle beam when incident on the detection unit in real time. This type of correction is an even finer correction which is not implemented globally, that is to say not implemented equally for all second individual particle beams. However, it is generally desirable for the detection unit to meet further desired properties in that case; for example, it is the case that the deviation of a specific second individual particle beam from its reference position can only be detected if the associated detection region is arranged adjacent, or in great relative proximity, to the additional detection channel detecting the deviation. Examples enabling this detection are presented in more detail below. By way of example, a multi-deflector array can be used for the individual positional deviation correction, which multi-deflector array is arranged, for example, in the secondary path in the direction of the particle optical beam path after the so-called anti-scan.

According to an embodiment of the disclosure, the positional deviation is only corrected if a threshold value is exceeded. This prevents basically superfluous corrections from being carried out. Even if the second individual particle beams are projected in focused fashion on their respective detection regions, it naturally nevertheless is the case that the focus does not consist of a mathematical point but instead has an extent, albeit a small extent. Thus, strictly speaking, the intensity of each second individual particle beam has an intensity distribution when incident on the detection surface. Thus, a signal may only be detected bit by bit or gradually via the additional detection channels in the case of a deviation. For example, it is possible that the vast majority of the detection of the second individual particle beam is still carried out correctly via the assigned detection region. Should this be the case, it may not be necessary to correct the detected but insignificant positional deviation. Only once a threshold-which may be defined in advance-is exceeded is it, in general, desirable to actually correct the positional deviation.

The above-described embodiment variants according to the first aspect of the disclosure can be combined with one another in full or in part, provided that no technical contradictions arise as a result.

According to a second aspect, the disclosure provides a computer program product having a program code for carrying out the method as described above in a plurality of embodiments. In this case, the program code can be divided into one or more partial codes. The program code can be written in any desired programming language.

According to a third aspect, the disclosure provides a multi-beam particle microscope configured to carry out the method according to any one of the preceding exemplary embodiments.

According to a fourth aspect, the disclosure provides a multi-beam particle microscope comprising the following:
a multi-beam particle source, configured to generate a first field of a plurality of charged first individual particle beams;
a first particle optical unit with a first particle optical beam path, configured to image the generated first individual particle beams onto an object plane such that the first individual particle beams impinge an object at incidence locations, which form a second field;
a detection unit with a plurality of detection regions which form a third field, with each of these detection regions being fixedly assigned a detection channel or a plurality of detection channels and with the same detection unit moreover comprising additional detection channels which are not assigned to any of the detection regions;
a second particle optical unit with a second particle optical beam path, configured to image, in substantially focused fashion, second individual particle beams, which emanate from the incidence locations in the second field, onto the third field of the detection regions of the detection system;
with the second particle optical unit comprising a fast detection position adjustment mechanism configured to correct a position of the second individual particle beams when incident on the detection unit in real time;
an objective lens, through which both the first and the second individual particle beams pass;
a beam switch, which is arranged in the first particle optical beam path between the multi-beam particle source and the objective lens and which is arranged in the second particle optical beam path between the objective lens and the detection unit;
a controller;
with the controller being configured to control the second particle optical unit,
with the controller being configured to generate individual images from data obtained via signals from the detection regions with the respective fixedly assigned detection channel or the respective fixedly assigned detection channels;
with the controller being configured to determine a positional deviation of the second individual particle beams from a reference incidence position when incident on the detection unit from data obtained via signals from the additional detection channels which are not assigned to any of the detection regions, and to generate at least one correction signal serving to correct a positional deviation, and
with the controller being configured to control the fast detection position adjustment mechanism in real time using the at least one correction signal.

The multi-beam particle microscope according to the fourth aspect of the disclosure is configured and suitable for carrying out the method according to the disclosure according to the first aspect of the disclosure. All explanations and definitions made in the context of the first and/or second and/or third aspect of the disclosure also apply to the fourth aspect of the disclosure.

The fast detection position adjustment mechanism of the multi-beam particle microscope according to the disclosure can be designed in one part or multiple parts. It is possible that each mechanism of the detection position adjustment mechanism serves the (predominant) correction of a certain class of positional deviation or image aberration (e.g., displacement, rotation, magnification, anamorphic imaging). The detection position adjustment mechanism allows a correction of the position of the second individual particle beams when incident on the detection unit in real time and consequently still allows this during an inspection task and, in particular, still during the generation of one or more individual images. Expediently, there is therefore high-frequency control of the fast detection position adjustment mechanism.

The controller of the multi-beam particle microscope can likewise be formed in one part or in multiple parts. By way of example, it may comprise one or more control computers or other controllers; it may also be subdivided into a plurality of modules. The at least one correction signal serving to correct the positional deviation may in turn represent a single signal or a superposition of a plurality of signals. The method involves the fast detection position adjustment mechanism for positional correction can be meaningfully controlled via the signal or signals. By way of example, it is possible that a signal or a set of signals is used to correct a certain image aberration or a certain class of positional deviations and, accordingly, one or more other correction signals or a corresponding set is used to correct other image aberrations or a different class of positional deviations. By way of example, the number of correction signals corresponds to the number of individually controllable particle optical constituent parts of the fast detection position adjustment mechanism.

According to an embodiment of the disclosure, the detection unit comprises an image generation detection region in which all detection regions are arranged, and the detection unit comprises an adjustment detection region in which all additional detection channels are arranged. Such a subdivision of the detection unit into two functionally different regions is always possible as a matter of principle; both the image generation detection region and the adjustment detection region can be formed as a connected region or as a non-connected region in this case. Expressed differently, both the image generation detection region and the adjustment detection region may comprise subregions. Especially in those cases where each detection region of the image generation detection region comprises exactly one detection channel, it is possible that the detection unit itself comprises only similar or structurally identical detection channels, to be precise both normal detection channels for image recording and also additional detection channels for adjustment purposes. In that case, the subdivision of the detection unit into, firstly, an image generation detection region and, secondly, an adjustment detection region need not be made purely on the basis of the physical unit or structural unit, but very much by the fixed and hence unchanging assignment during the signal evaluation within the scope of the detection.

According to an embodiment of the disclosure, the image generation detection region is path-connected, and the adjustment detection region is likewise path-connected. In this context, the term “path-connected” is used as defined in topology. In this case, the definition of the regions, strictly speaking, is simplifying and a region is defined as a two-dimensional space and hence as a subspace of Rn. If both the image generation detection region and the adjustment detection region are respectively path-connected, then this is equivalent in the two-dimensional subspace of R″ to the statement that the image generation detection region and the adjustment detection region each form a domain. The arrangement of the two domains with respect to one another in the form of path-connected regions is possible in different ways in this case.

According to an embodiment of the disclosure, the adjustment detection region is arranged around the outside of the image generation detection region. This nesting of the two regions may be rotationally symmetric or else have an n-fold symmetry about the centre of both regions, but this is not mandatory. Alternatively, it is for example also possible that the image generation detection region is arranged around the outside of the adjustment detection region. Once again, this can be implemented symmetrically and in particular rotationally symmetrically or with an n-fold symmetry, but irregular non-symmetrical arrangements are also possible. If the adjustment detection region is arranged symmetrically around the outside of the image generation detection region, then this can be desirable for an evaluation of signals in the context of determining a positional deviation of the raster of second individual particle beams since the signal evaluation can be implemented particularly easily in this case. It is also comparatively easy to distinguish between different classes/types of positional deviations. Moreover, the effects of a global positional deviation are particularly large in the edge regions of the raster, and consequently particularly easy to detect. However, naturally, there are also other detection options and ultimately a skilful choice of the physical design of the detection unit also plays a role in this case.

According to an embodiment of the disclosure, the image generation detection region is not path-connected, and the adjustment detection region is path-connected but not simply connected. Here, too, the terms “not path-connected” and “simply connected” are used as is conventional in topology. This embodiment of the disclosure vividly describes at least two spatially separated detection regions (domains) being embedded in the adjustment detection region. Naturally, it is also possible that it is not only two detection regions but every detection region of the image generation detection region that is individually embedded in the adjustment detection region. Then again, the arrangement of image generation detection region and adjustment detection region arising overall as a result may have a regular or irregular, symmetric or non-symmetric design. A further example of a set-up according to this embodiment variant of the disclosure is a cruciform arrangement of the adjustment detection region, which divides the image generation detection region, which is not path-connected, into four subregions (four domains) as a result. Various further embodiments are possible.

According to an embodiment of the disclosure, each detection region is at least partly surrounded by additional detection channels. This comparatively comprehensive embedding of the detection regions into the additional detection channels for adjustment detection purposes allows, for example, not only a global identification of positional deviations of the entire raster of second individual particle beams but also an individual identification of positional deviations of each second individual particle beam.

According to an embodiment of the disclosure, the additional detection channels are arranged so that a positional deviation in the form of a directional deviation of at least one second individual particle beam from its reference incidence position, in particular of a plurality of the second individual particle beams from their respective reference incidence positions, is detectable. In the process, it is therefore not only the absolute value of the positional deviation that is determined but also the direction of the positional deviation. By way of example, on account of the position of the additional detection channels supplying a signal, it is possible to deduce the direction of the positional deviation.

According to an embodiment of the disclosure, each detection region comprises exactly one detection channel. In this case, the structure of the detection unit overall is particularly simple.

According to an embodiment of the disclosure, all detection channels are structurally identical. This therefore means that both the detection channels which define one or more detection regions and the additional detection channels for detecting the positional deviations are structurally identical. In this case, too, the detection unit overall has a particularly simple design.

Alternatively, it is naturally also possible that the detection channels differ. By way of example, it is possible to realize detection channels fixedly assigned to the detection regions in accordance with a first structure and realize the additional detection channels for the detection of the positional deviations in accordance with a second structure, with the first structure and the second structure not being identical. In the process, it is possible to adapt the additional detection channels in terms of their design to their special task, specifically the identification of positional deviations. By way of example, should the detection of a displacement of the raster of second individual particle beams be desirable, then this can already be easily implemented using an edge-shaped and strip-shaped additional detection channel, for example. A person skilled in the art will identify further embodiments without leaving the scope of protection of the disclosure as a result.

According to an embodiment of the disclosure, each detection channel comprises a signal entrance surface, wherein the signal entrance surfaces overall are arranged as a hexagon. A surface can be tessellated using such a hexagonal arrangement and it is particularly easy to compose multi-image fields from individual image fields. In the process, 3n (n−1)+1 individual particle beams can be used for image generation and detection.

According to an embodiment of the disclosure, each detection region is fixedly assigned exactly one detection channel, and the additional detection channels not assigned to any detection region are arranged hexagonally around the outside of the detection regions. Hexagonal arrangements can easily be extended in this way and existing concepts for detection units also only need to be spatially extended but not be modified in detail from a structural point of view.

According to an embodiment of the disclosure, the detection system comprises one or more particle detectors or consists of one or more particle detectors. Alternatively, the detection system comprises one or more particle detectors and also a plurality of light detectors disposed downstream thereof. Thus, the disclosure can be flexibly implemented with respect to the detection system or detection unit; there is no principle binding to a specific design of the detection system.

According to an embodiment of the disclosure, each detection channel comprises exactly one optical fibre and different detection channels comprise different optical fibres.

According to an embodiment of the disclosure, a detection channel comprises no optical fibre and an array of light-sensitive detectors, in particular an array comprising photomultipliers, photodiodes or avalanche photodiodes, is provided as the light detection system. These are all examples for the flexible choice of a detection system or detection unit.

According to an embodiment of the disclosure, the fast detection position adjustment mechanism comprises at least one of the following: an electrostatic lens, an electrostatic deflector, an electrostatic stigmator, an air-core coil, a multi-deflector array. Other fast detection position adjustment mechanisms can also be used and are known to a person skilled in the art. Here, reference is made once again to the above-cited documents.

The various embodiments and aspects of the disclosure can be combined with one another in full or in part, provided that no technical contradictions arise as a result.

### BRIEF DESCRIPTION OF THE DRAWINGS

The disclosure will be understood even better with reference to the accompanying figures, in which:

FIG. 1: shows a schematic illustration of a multi-beam particle microscope (MSEM);

FIG. 2A: schematically shows a detection system of a multi-beam particle microscope;

FIG. 2B: schematically shows a detection system of a multi-beam particle microscope;

FIG. 3: schematically shows a controller of a multi-beam particle microscope with real-time readjustment of second individual particle beams when incident on a detection unit;

FIG. 4: schematically shows aspects of the method according to the disclosure;

FIG. 5: schematically shows detection of focused secondary beams in a normal inspection mode;

FIGS. 6A-6B: schematically show a principle of a positional deviation correction;

FIGS. 7A-7B: schematically show a detection unit extended with additional detection channels;

FIGS. 8A-8B: schematically show a detection unit extended with additional detection channels;

FIGS. 9A-9B: schematically show a detection unit extended with additional detection channels;

FIGS. 10A-10C: schematically show positional deviations of second individual particle beams when incident on a detection unit;

FIGS. 11A-11D: schematically show various regions of a detection unit and various positions/positional deviations of second individual particle beams when incident on a detection unit;

FIG. 12: schematically shows a detection unit with detection regions which are fixedly assigned a plurality of detection channels, and with additional detection channels for detecting a positional deviation when second individual particle beams are incident on the detection unit;

FIGS. 13A-13B: schematically show a subdivision of a detection unit into different regions for the purpose of determining and correcting positional deviations when second individual particle beams are incident on the detection unit; and

FIG. 14: schematically shows a further detection unit with detection regions which are fixedly assigned a plurality of detection channels, and with additional detection channels for detecting a positional deviation when second individual particle beams are incident on the detection unit.

### DETAILED DESCRIPTION

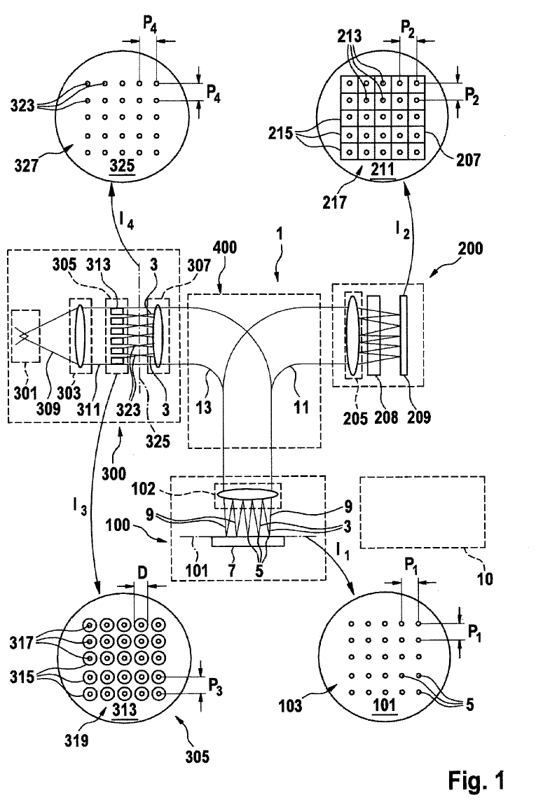

FIG. 1 is a schematic illustration of a particle beam system 1 in the form of a multi-beam particle microscope 1, which uses a plurality of particle beams. The particle beam system 1 generates a plurality of particle beams which are incident on an object to be examined in order to generate there interaction products, for example secondary electrons, which emanate from the object and are subsequently detected. The particle beam system 1 is of the scanning electron microscope (SEM) type, which uses a plurality of primary particle beams 3 which are incident on a surface of the object 7 at a plurality of locations 5 and produce there a plurality of electron beam spots, or spots, that are spatially separated from one another. The object 7 to be examined can be of any desired type, for example a semiconductor wafer or a biological sample, and can comprise an arrangement of miniaturized elements or the like. The surface of the object 7 is arranged in a first plane 101 (object plane) of an objective lens 102 of an objective lens system 100.

The enlarged detail I1 in FIG. 1 shows a plan view of the object plane 101 having a regular rectangular field 103 of incidence locations 5 formed in the first plane 101. In FIG. 1, the number of incidence locations is 25, which form a 5×5 field 103. The number 25 of incidence locations is a number chosen for reasons of simplified illustration. In practice, the number of beams, and hence the number of incidence locations, can be chosen to be significantly greater, such as, for example, 20×30, 100×100 and the like.

In the illustrated embodiment, the field 103 of incidence locations 5 is a substantially regular rectangular field having a constant pitch P1 between adjacent incidence locations. Exemplary values of the pitch P1 are 1 micrometre, 10 micrometres and 40 micrometres. However, it is also possible for the field 103 to have other symmetries, such as a hexagonal symmetry, for example.

A diameter of the beam spots formed in the first plane 101 can be small. Exemplary values of the diameter are 1 nanometre, 5 nanometres, 10 nanometres, 100 nanometres and 200 nanometres. The focusing of the particle beams 3 for shaping the beam spots 5 is carried out by the objective lens system 100.

The primary particles incident on the object generate interaction products, for example secondary electrons, backscattered electrons or primary particles that have experienced a reversal of movement for other reasons, which emanate from the surface of the object 7 or from the first plane 101. The interaction products emanating from the surface of the object 7 are shaped by the objective lens 102 to form secondary particle beams 9. The particle beam system 1 provides a particle beam path 11 for guiding the plurality of secondary particle beams 9 to a detector system 200. The detector system 200 comprises a particle optical unit with a projection lens 205 for directing the secondary particle beams 9 at a particle multi-detector 209.

The detail 12 in FIG. 1 shows a plan view of the plane 211, in which individual detection regions 215 of the particle multi-detector 209 on which the secondary particle beams 9 are incident at locations 213 are located. The incidence locations 213 lie in a field 217 with a regular pitch P2 from one another. Exemplary values of the pitch P2 are 10 micrometre, 100 micrometres and 200 micrometres.

The primary particle beams 3 are generated in a beam generating apparatus 300 comprising at least one particle source 301 (e.g., an electron source), at least one collimation lens 303, a multi-aperture arrangement 305 and a field lens 307. The particle source 301 generates a diverging particle beam 309, which is collimated or at least substantially collimated by the collimation lens 303 in order to shape a beam 311 which illuminates the multi-aperture arrangement 305.

The detail 13 in FIG. 1 shows a plan view of the multi-aperture arrangement 305. The multi-aperture arrangement 305 comprises a multi-aperture plate 313, which has a plurality of openings or apertures 315 formed therein. Midpoints 317 of the openings 315 are arranged in a field 319 that is imaged onto the field 103 formed by the beam spots 5 in the object plane 101. A pitch P3 between the midpoints 317 of the apertures 315 can have exemplary values of 5 micrometres, 100 micrometres and 200 micrometres. The diameters D of the apertures 315 are smaller than the pitch P3 between the midpoints of the apertures. Exemplary values of the diameters D are 0.2×P3, 0.4×P3 and 0.8×P3.

Particles of the illuminating particle beam 311 pass through the apertures 315 and form particle beams 3. Particles of the illuminating beam 311 which are incident on the plate 313 are absorbed by the latter and do not contribute to the formation of the particle beams 3.

On account of an applied electrostatic field, the multi-aperture arrangement 305 focuses each of the particle beams 3 in such a way that beam foci 323 are formed in a plane 325. Alternatively, the beam foci 323 can be virtual. A diameter of the beam foci 323 can be, for example, 10 nanometres, 100 nanometres and 1 micrometre.

The field lens 307 and the objective lens 102 provide a first imaging particle optical unit for imaging the plane 325, in which the beam foci 323 are formed, onto the first plane 101 such that a field 103 of incidence locations 5 or beam spots arises there. Should a surface of the object 7 be arranged in the first plane, the beam spots are correspondingly formed on the object surface.

The objective lens 102 and the projection lens arrangement 205 provide a second imaging particle optical unit for imaging the first plane 101 onto the detection plane 211. The objective lens 102 is thus a lens that is part of both the first and the second particle optical unit, while the field lens 307 belongs only to the first particle optical unit and the projection lens 205 belongs only to the second particle optical unit.

A beam switch 400 is arranged in the beam path of the first particle optical unit between the multi-aperture arrangement 305 and the objective lens system 100. The beam switch 400 is also part of the second optical unit in the beam path between the objective lens system 100 and the detector system 200.

Further information relating to such multi-beam particle beam systems and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is fully incorporated by reference in the present application.

The multiple particle beam system furthermore comprises a computer system 10 configured both for controlling the individual particle optical components of the multiple particle beam system and for evaluating and analyzing the signals obtained using the multi-detector 209 or the detection unit 209. It can also be used to carry out the method according to the disclosure. The computer system 10 can be constructed from a plurality of individual computers or components.

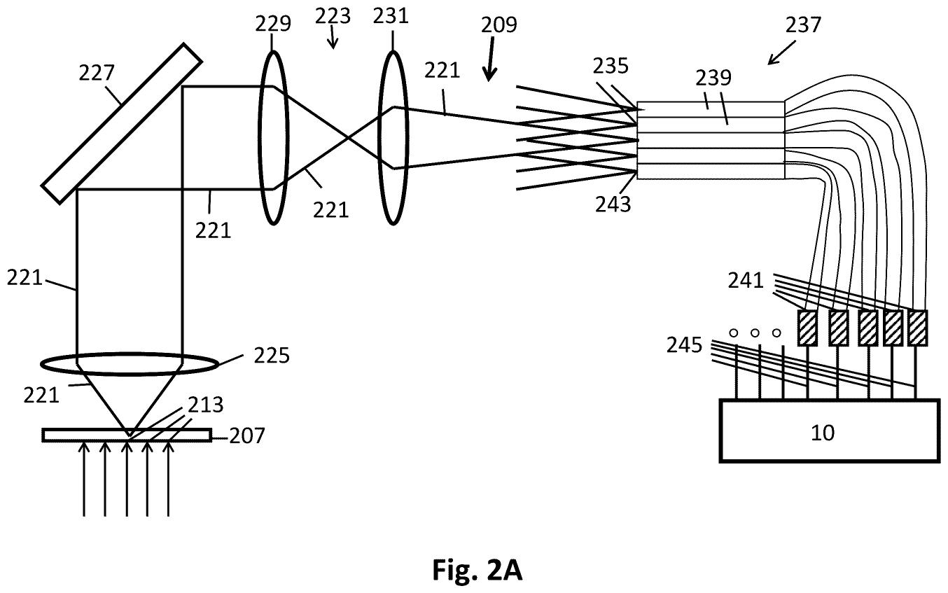

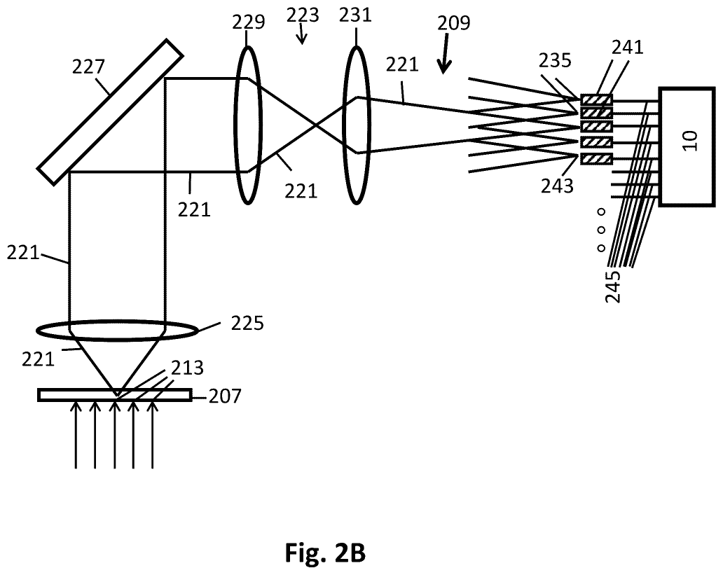

FIG. 2A is a schematic illustration for elucidating a realization of the detector 209 in exemplary fashion. In this case, the detector 209 comprises a scintillator plate 207 as particle detector, onto which scintillator plate the interaction products, for example secondary electron beams, are directed by an electron optical unit. The electron optical unit comprises, if integrated into the multi-beam particle microscope from FIG. 1, the electron optical components of the particle optical unit which shape the electron beams 9, that is to say, for example, the objective lens 102, which direct the electron beams 9 towards the detector 209, such as, for example, the beam switch 400, and which focus the electron beams 9 on the surface of the scintillator plate 207, such as, for example, the lens 205. The electron beams 9 are incident on the scintillator plate 207 at incidence locations 213. Even if the electron beams 9 are focused on the surface of the scintillator plate 207, beam spots having diameters that are not arbitrarily small are formed on the surface. The midpoints of the beam spots can be regarded as the incidence locations 213, which are arranged at the pitch P₂ (cf. FIG. 1) from one another.

The scintillator plate 207 contains a scintillator material, which is excited to emit photons by the incident electrons of the electron beams 9. Each of the incidence locations 213 thus forms a source of photons. FIG. 2A illustrates just a single corresponding beam path 221 emanating from the incidence location 213 of the central electron beam of the five electron beams 9 illustrated. The beam path 221 passes through a light optical unit 223, which comprises a first lens 225, a mirror 227, a second lens 229 and a third lens 231 in the example shown, and then impinges on a light receiving surface 235 (signal entrance surface 235) of a light detection system 237. The light receiving surface 235 is formed by an end face of an optical fibre 239, into which at least one portion of the photons is coupled and guided to a light detector 241. The light detector 241 can comprise for example a photomultiplier, an avalanche photodiode, a photodiode or other types of suitable light detectors. The light optical unit 223 is configured such that it optically images the surface 208 of the scintillator plate 207 into a region 243 in which the light receiving surface 235 is arranged. On account of this optical imaging, optical images of the incidence locations 213 are generated in the region 243. In the region 243, a separate light receiving surface 235 of the light detection system 237 is provided for each of the incidence locations 213. Each of the further light receiving surfaces 235 (signal entrance surfaces 235) is formed by an end face of a light guide 239, which guides the light coupled into the end face to a light detector 241. On account of the optical imaging, a light receiving surface 235 is assigned to each of the incidence locations 213, wherein the light entering a respective light receiving surface 235 is detected by a separate light detector 241. The light detectors 241 output electrical signals via signal lines 245. The electrical signals represent intensities of the particle beams 9. Consequently, the locations on the surface of the scintillator plate 207 which are imaged onto the light receiving surfaces of light detectors 241 define different detection points or detection regions. On account of the electron optical unit described above, interaction products, for example electrons, which emanate from two different individual field regions of an object are also projected onto different detection regions 215 of the scintillator plate 207. In the exemplary embodiment explained here, the light detectors 241 are arranged at a distance from the light receiving surfaces 235, onto which the light optical unit 223 images the scintillator plate 207, and the received light is guided to the light detectors 241 through optical fibres 239. However, it is also possible for the light detectors 241 to be arranged directly where the light optical unit generates the image of the scintillator plate and the light-sensitive surfaces of the light detectors thus form the light receiving surfaces.

In this case, FIG. 2A merely schematically elucidates some details of the detector 209. It should still be pointed out at this juncture that by virtue of the scanning movement of the primary particle beams over an object or a sample, many points of the sample are irradiated or scanned. In this case, each primary particle beam 3 sweeps wholly or partly over an individual field region of the object 7. In this case, each primary particle beam 3 is allocated a dedicated individual field region of the object. From these individual field regions of the object 7, interaction products, for example secondary electrons, then in turn emanate from the object 7. The interaction products are then projected onto the detection regions 215 of the particle detector or onto the scintillator plate 207 in such a way that the interaction products emanating from two different individual field regions are projected onto different detection regions 215 of the scintillator plate 207. Light signals are emitted by each detection region 215 of the scintillator plate 207 when the interaction products, for example secondary electrons, are incident on the detection region 215, wherein the light signals emitted by each detection region 215 are fed to a light detector 241 assigned to the respective detection region. In other words, the situation is that each primary particle beam 3 comprises its own detection region 215 on the scintillator 207 and also its own light detector 241, which together form a detection channel 235 in the example shown. Thus, in the example shown, each detection region 215 comprises exactly one detection channel 235, which is fixedly assigned to its detection region 215.

FIG. 2B shows an alternative embodiment variant of a detection system 209. In this variant, no optical fibres 239 are provided; instead, photons emanating from the scintillator plate 207, after the optical imaging, impinge directly on an array having light-sensitive detectors 241, for example an array comprising photomultipliers, photodiodes or avalanche photodiodes.

Detection architectures other than the ones illustrated in FIG. 2A and FIG. 2B are also suitable for carrying out the method according to the disclosure for operating a multi-beam particle microscope 1. Reference is made, for example, to the method of DED (“direct electron detection”), which manages without light detectors and in which secondary electrons are directly converted into a current signal. In this case, use can be made in particular of those detection architectures in which each detection region is in each case fixedly assigned a plurality of detection channels 235. This multiple assignment of detection channels to one detection region occurs, in particular in pixelated or sectored detectors, frequently.

According to the disclosure, additional detection channels 235′ are now added to supplement to the detection regions of the detection unit 209 used in certain known systems. To this end, the existing detection unit 209 can be extended by additional detection channels 235′, which are not assigned to any detection region 215. Various exemplary embodiments of a corresponding multi-beam particle microscope 1 according to the disclosure or of the associated detection unit 209 will be described below. The additional detection channels 235′ serve as a measuring member for detecting a positional deviation of the second individual particle beams 9 when incident on the detection regions 215. This is because if the additional detection channels 235′ do not detect a signal or at least do not detect a significant signal (threshold value has not been reached), then the assumption can be made that the second individual particle beams 9 are incident sufficiently accurately on the detection regions 215. It is possible to correct the positional deviation in real time on the basis of the determined positional deviation and for example via the one part or multi-part fast detection position adjustment mechanism in the secondary path of the multi-beam particle microscope 1, in particular still during the recording of the plurality of individual images.

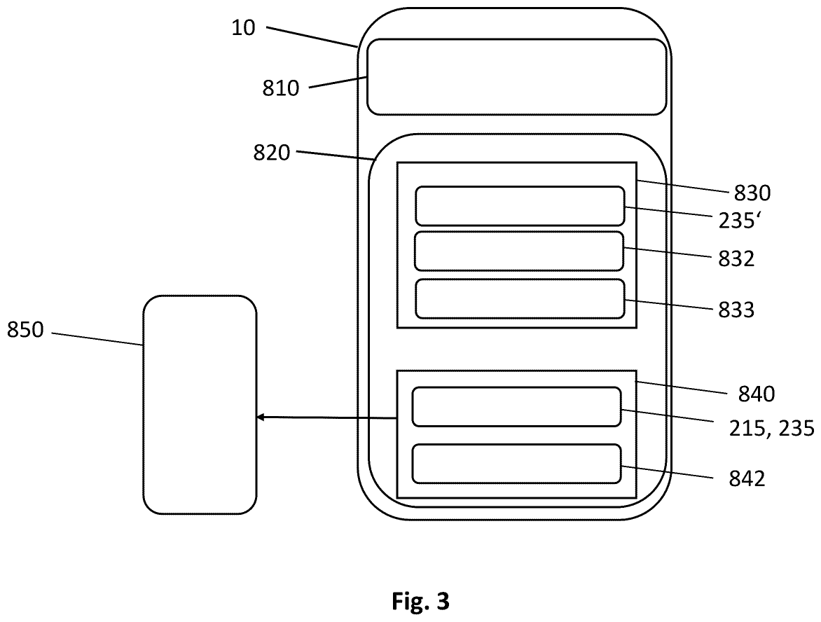

FIG. 3 schematically shows a controller 10 of a multi-beam particle microscope 1 with real-time readjustment of second individual particle beams 9 when incident on a detection unit 209. In the example shown, the controller 10 comprises a controller 810 for the primary path and a controller 820 for the secondary path. In turn, the controller 820 for the secondary path comprises an adjustment control module 830 and an image generation control module 840. Moreover, the controller 820 for the secondary path may comprise further modules, but these are not illustrated in FIG. 3.

The image generation control module 840 processes data which were obtained via signals from the detection regions 215 with their fixedly assigned detection channels 235. Individual images and, from these, composite multi-images which can be displayed via an image display unit 850 are generated via image generation algorithms 842. In this respect, the controller 10 illustrated in FIG. 3 or the controller 820 corresponds to the controller already known.

According to the disclosure, the adjustment control module 830 is now implemented within the controller 10. As measuring member, this adjustment control module 830 comprises additional detection channels 235′, which are not assigned to any of the detection regions 215. Instead, these additional detection channels 235′ serve to detect a positional deviation of the second individual particle beams 9 when incident on the detection unit 209. The adjustment control module 830 is configured to determine a positional deviation of the second individual particle beams 9 from a reference incidence position when incident on the detection unit 209 from data obtained via signals from each of the additional detection channels 235′ which are not assigned to any of the detection regions 215, and to generate at least one correction signal serving to correct the positional deviation. Algorithms 832 can be used to evaluate the signals and to generate the at least one correction signal. The one or more detection position adjustment mechanisms 833 as actuator or actuators is/are controlled via the correction signal or via the correction signals. This control is implemented in real time, that is to say still while an individual image or a plurality of individual images are generated.

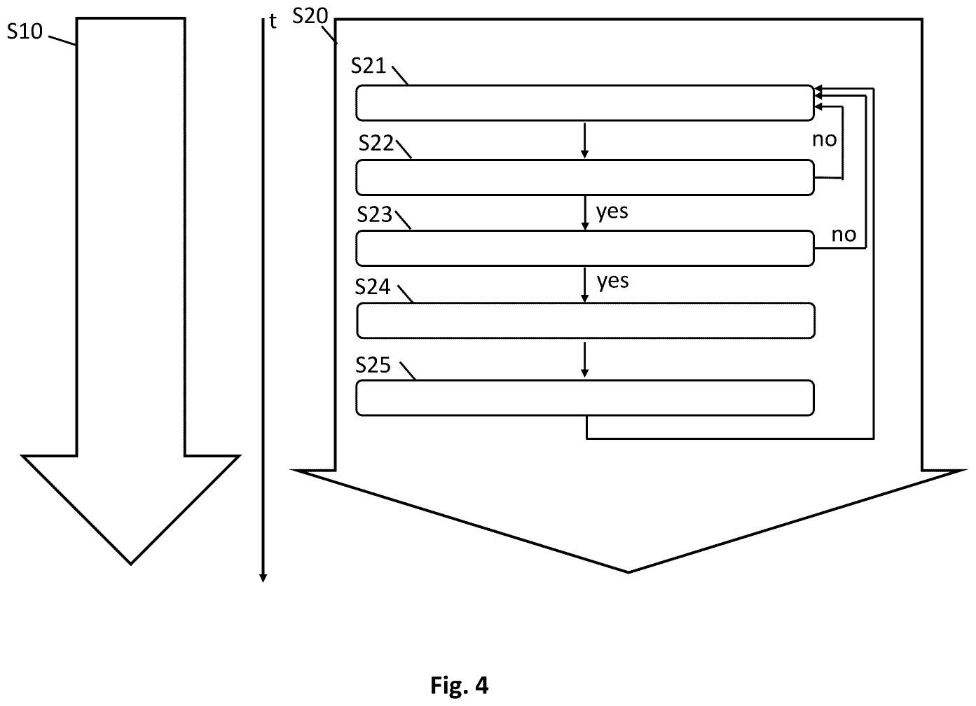

FIG. 4 schematically shows aspects of the method according to the disclosure for operating a multi-beam particle microscope 1 in an inspection mode of operation: FIG. 4 illustrates, parallel to the time axis t, firstly an image generation step S10 and secondly steps for positional deviation identification and correction S20. The steps or sequences of steps S10 and S20 are depicted within large arrows, which are intended to illustrate the parallelism of the executed steps. During the image generation process according to the sequence of steps S10, the following steps, for example, can be carried out parallel in time according to the disclosure: The additional detection channels 235′ are read in a step S21. Whether there is a positional deviation of the second individual particle beams 9 when incident on the detection unit 209 is determined in a further step S22. Step S21 is carried out again if this is not the case. If a positional deviation is determined in S22 instead, the method continues with S23 and there is a determination as to whether a threshold value is exceeded. Step S21 is carried out again and the method is continued with the readout of the additional detection channels 235′ if this is not the case. By contrast, if a threshold value is reached, at least one correction signal is generated in a next step S24 and used in step S25 to control the one or more detection position adjustment mechanisms. Subsequently, step S21 is carried out again and the additional detection channels 235′ are read out again. Optionally, it is also possible that the identified positional deviation is classified whenever a threshold value being exceeded is determined in step S23. This classification can then be included in the algorithm for generating a correction signal or for generating correction signals in step S24. Positional deviations corrected in this way are, for example, a displacement, a rotation of the raster of second individual particle beams 9, a magnification or anamorphic imaging.

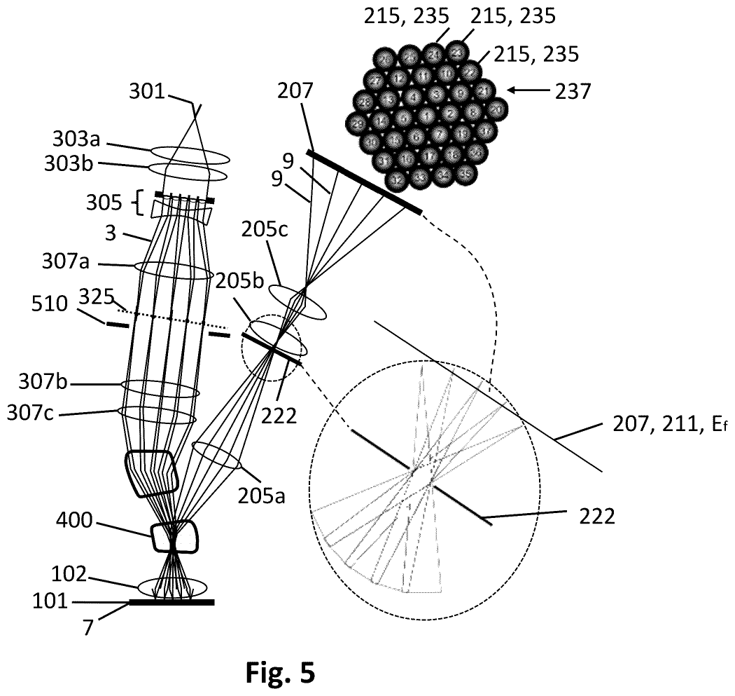

FIG. 5 schematically shows a detection of focused secondary beams 9 that is known, in principle. A particle source 301 emits a divergent particle beam, which, in the example shown, passes through a condenser lens system 303a, 303b and, in the example shown, impinges in a collimated fashion on a multi-beam particle generator 305 and passes through the latter. The generator can comprise for example a multi-aperture plate with a downstream counter-electrode, but other embodiment variants are also possible. Theoretically it is also possible, of course, to use a multi-beam particle source 301 directly, such that the first individual particle beams 3 do not have to be formed separately by a multi-beam particle generator 305.

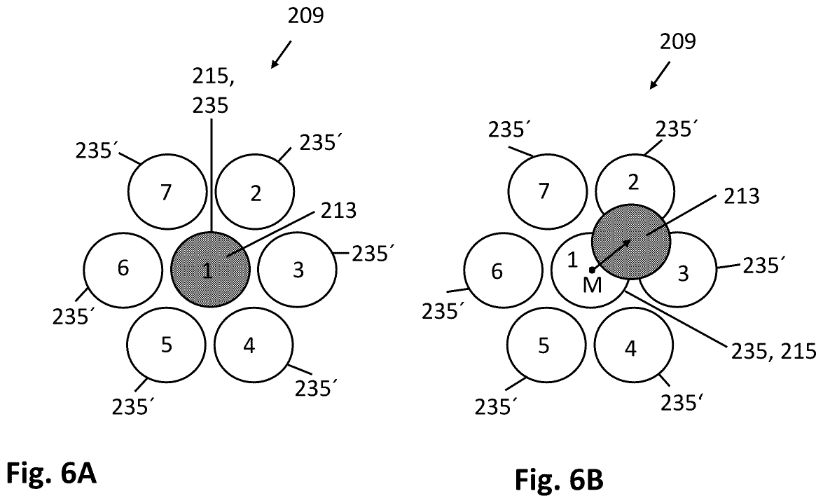

In the further particle optical beam path, in the example illustrated, the first individual particle beams 3 pass through a field lens system having the field lenses 307a, 307b and 307c. Afterwards, they pass through a beam switch 400 and also an in particular magnetic objective lens 102, and then the first individual particle beams 3 are incident in a focused fashion on the object 7 in the object plane 101. The incidence of the first individual particle beams 3 triggers the emergence of the second individual particle beams 9 from the sample or the object 7. The second individual particle beams likewise pass through the objective lens 102 and the beam switch 400 and also, in the example illustrated, subsequently a projection lens system 205a, 205b, 205c. In the projection lens system 205, a contrast stop 222 is arranged in a beam cross-over of the second individual particle beams 9. The contrast stop 222 can be a circular stop or a ring stop, for example. It can be a bright field stop or a dark field stop. The contrast stop has the task of filtering second individual particle beams 9 according to their starting angles from the object plane 101. Second individual particle beams 9 proceeding from/up to a specific starting angle range are cut out from the pencil of the second individual particle beams 9 in the beam cross-over. This is illustrated schematically in the circle shown in an enlarged view in FIG. 5. The beam path in FIG. 5—as already explained—is illustrated only schematically and thus in a greatly simplified manner. In the normal inspection mode illustrated in FIGS. 6A-6B, the second individual particle beams 9 are incident in a focused fashion on the detection plane 207 or the scintillator 207. Disposed downstream of the scintillator 207 is the light detector 237, which in FIG. 5 is illustrated schematically by the hexagonal arrangement of detection channels 1 to 37, the cross section or signal entrance surface of which is configured here as a circle. In the case of the imaging illustrated in FIG. 5, the situation is such that the object plane 101 is imaged in a focused fashion onto the scintillator 207 or the plane E_{f}. Moreover, the situation is such that optionally all the individual particle beams 3, 9 are used for the imaging in order to achieve the highest possible throughput during the imaging. In the example illustrated, the detection unit 209 comprises a particle detection unit and a downstream light-detection unit 237. In this case, each detection region 215 is fixedly assigned exactly one detection channel 235, as illustrated schematically in FIG. 5 on the basis of the light-detection unit 237.

FIGS. 6A-6B now schematically show a principle of a positional deviation correction according to the disclosure. In general, the detection unit 209 illustrated in FIG. 5 can be extended to this end. However, for reasons of clarity, FIGS. 6A-6B does not show a plurality of second individual particle beams 9; instead, the situation when a second individual particle beam 9 is incident on the detection unit 209 is illustrated for only one such beam: The detection unit 209 illustrated in exemplary fashion in FIGS. 6A-6B comprises a total of 7 detection channels 235, 235′. They are provided within the same detection plane. However, only the detection channel 235 denoted by order number 1 is fixedly assigned to a detection region 215; the signals generated by this channel 235 therefore serve exclusively for image generation. The additional detection channels 235′ are arranged in a ring-shaped hexagonal arrangement around the detection region 215 or the detection channel 235 fixedly assigned to this detection region 215. FIG. 6A) shows the situation during incidence of the second individual particle beam, depicted in exemplary fashion, on the detection unit 209 exactly at the reference incidence position: in the schematically shown example, the beam spot 213 is congruent with the detection region 215 and the detection channel 235 fixedly assigned thereto. The size relationships of beam spot 213 on the one hand and detection region 215 on the other hand may also be different; by way of example, the beam spot 213 may be significantly smaller than the detection region 215. At this point, reference is made yet again to the fact that the detection region 215 may also have a plurality of detection channels 235 fixedly assigned thereto.

FIG. 6B) shows the situation when the second individual particle beam is not incident on the reference position of the detection unit 209 but there is instead a positional deviation of the beam 9 in relation to the reference position. This is because the beam spot 213 is displaced in that case and the centre M of the detection region 215 is no longer congruent with the centre of the beam spot 213. The discrepancy or displacement is indicated by the arrow in FIG. 6B). Very generally, the additional detection channels 235′ detect a signal if a positional deviation is present. In the present example, this merely relates to two of the six additional detection channels 235′. The direction of the positional deviation of the beam spot 213 from the reference position can be deduced as it is known which additional detection channels 235′ detect a signal. In the example shown, these are the additional detection channels 235′ with the order numbers 2 and 3. The positional deviation is then detected in the top right direction.

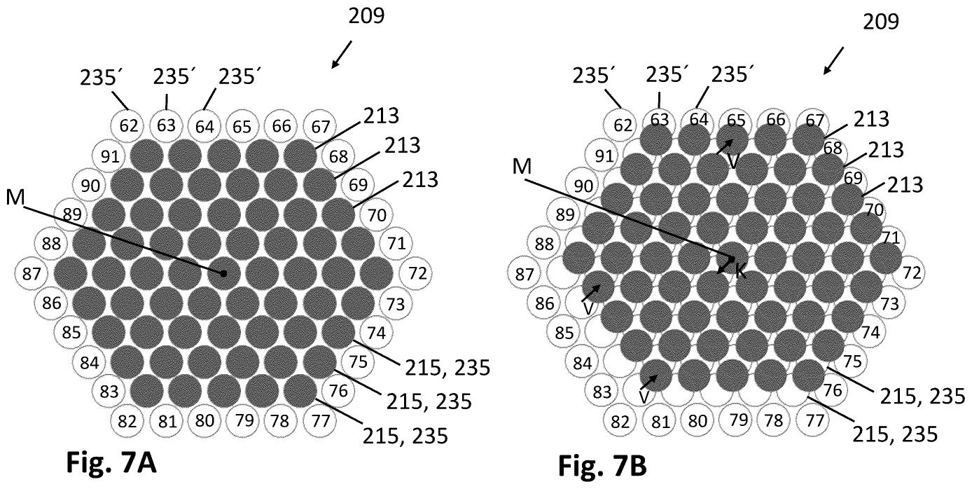

FIGS. 7A-7B schematically shows a detection unit 209 extended with additional detection channels 235′. The detection channels 235 and the additional detection channels 235′ are provided in the same detection plane. Depicted in this case is a raster of second individual particle beams 9, the beam spots 213 of which are depicted as dark in FIGS. 7A-7B. In FIG. 7A), these beam spots 213 are incident on the detection regions 215 in accordance with their optimal position or reference positions. Once again, each detection region 215 is fixedly assigned a detection channel 235; however, it would also be possible to fixedly assign to each detection region 215 a plurality of detection channels 235. In addition to the detection regions 215 with the fixedly assigned detection channels 235, the detection unit 209 comprises additional detection channels 235′, denoted with order numbers 62 to 91 in the example shown. In this case, the hexagonal arrangement of the detection regions 215 has been extended by a further shell in the example shown, that is to say the additional detection channels 235′ are also arranged hexagonally overall.

FIG. 7B) now illustrates the situation if a positional deviation of the raster of individual particle beams 9 is present when incident on the detection unit 209: The entire raster or all beam spots 213 has/have been displaced obliquely top right in the example shown. Three vectors V which indicate the displacement have been plotted in the figure in exemplary fashion. For this reason, the additional detection channels 235′ with order numbers 63 to 76 detect a signal. On the basis of which additional detection channels 235′ detect a signal and optionally also on the basis of the size of the signal, it is possible to determine the size of the displacement V in the example shown. Accordingly, a positional correction by the vector K is used so that the second individual particle beams 9 are able to be incident on the reference position in the detection regions 215 again.

Moreover, FIGS. 7A-7B is an example of a path-connected image generation detection region and a path-connected adjustment detection region: All detection regions 215 are arranged in the image generation detection region; this image generation detection region is a hexagon in the example shown. The adjustment detection region has all additional detection channels 235′ and is arranged around the outside of the image generation detection region in the example shown. In this case, the adjustment detection region itself is a hexagon shell.

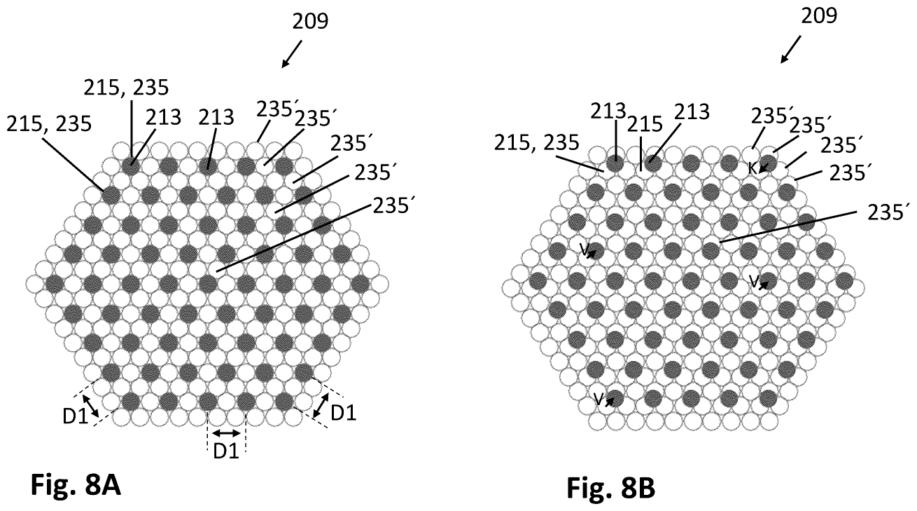

FIGS. 8A-8B schematically show a detection unit 209 extended with additional detection channels 235′. The detection channels 235 and the additional detection channels 235′ are provided in the same detection plane 211. In contrast with the detection unit 209 shown in FIGS. 7A-7B, the detection unit 209 in FIGS. 8A-8B has a greater number of additional detection channels 235′. Unlike in FIGS. 7A-7B, the detection regions 215 are not arranged in a path-connected region and consequently not arranged in a domain. Instead, the image generation detection region is not path-connected in FIGS. 8A-8B. Specifically, in the example shown, each detection region 215 is surrounded by six additional detection channels 235′. Like in FIGS. 7A-7B, the adjustment detection region in FIGS. 8A-8B is path-connected, but it is not simply connected. Thus, it is not possible to contract any closed path in the adjustment detection region to form a point; specifically, this is not the case if this path is placed around a detection region 215.

FIG. 8A) shows the situation in the case of an incidence of the plurality of individual particle beams 9 on the detection unit 209 at their respective reference position. By contrast, FIG. 8B) shows the situation when a positional deviation is present. In the example shown, various additional detection channels 235′ detect a signal if a positional deviation is present. In the case of the illustrated 61 secondary beams 9 with their associated beam spots 213, 2×61 additional detection channels 235′ detect a signal which allows a positional deviation to be deduced. Using the set-up illustrated in FIGS. 8A-8B, it is possible to detect both a global positional deviation and, in general, an individual positional deviation of individual particle beams 9. To this end, an additional detection channel 235′ is in each case located between two detection regions or the respective detection channels 235 fixedly assigned thereto. The corresponding distance D1 between two detection regions 215 is likewise plotted in FIGS. 8A-8B.

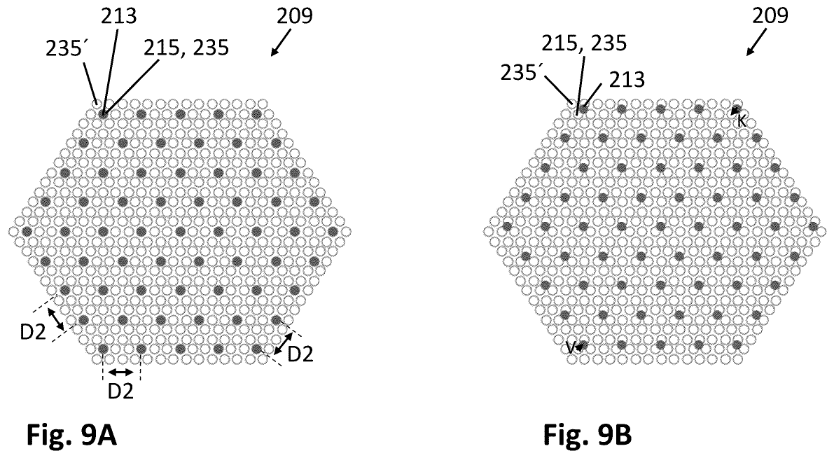

FIGS. 9A-9B schematically show a detection unit 209 extended with additional detection channels 235′. The detection channels 235 and the additional detection channels 235′ are provided in the same detection plane. In comparison with FIGS. 8A-8B, even more additional detection channels 235′ are provided according to FIGS. 9A-9B. The distance between detection regions 215 is denoted by D2; two additional detection channels 235′ are located between two detection regions 215 or the exactly one fixedly assigned detection channel 235. An even finer positional deviation can be determined using these additional detection channels 235′; however, the signal evaluation may be more complex.

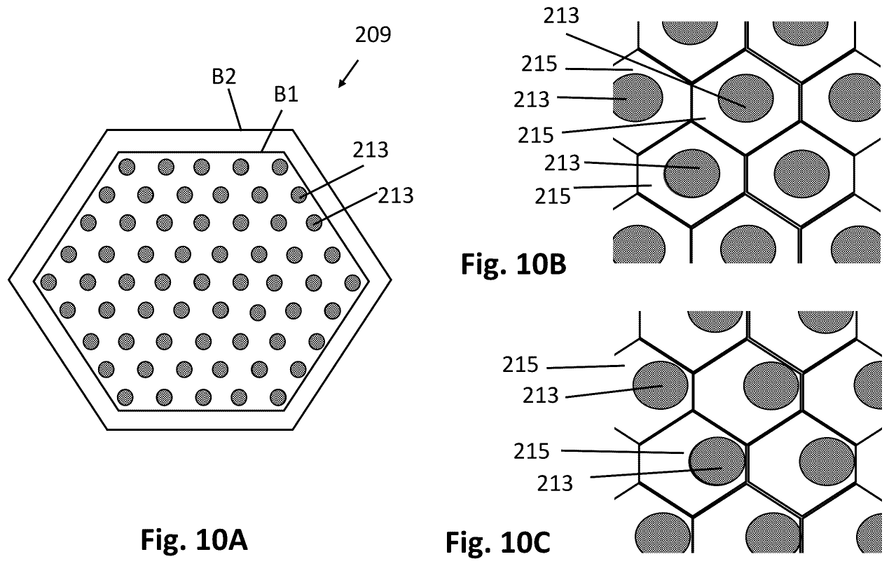

FIGS. 10A-10C schematically shows positional deviations of second individual particle beams 9 when incident on a detection unit 209. The detection unit 209 is schematically subdivided into the image generation detection region B1 and the adjustment detection region B2. The beam spots 213, which are incident only on the image generation detection region B1 in FIG. 10A), are also illustrated. The image generation detection region B1 and the adjustment detection region B2 are provided in the same plane. The image generation detection region B1 and the adjustment detection region B2 may in this case be equipped with detection channels and additional detection channels, respectively, which are not illustrated as such in detail in FIG. 10A).

By contrast, FIG. 10B) shows a portion from the image generation detection region B1, with a plurality of detection regions 215 being illustrated. In the example shown, these detection regions 215 are hexagonal and can have a pixelated or non-pixelated form. In any case, they comprise a fixed number of detection channels 235 fixedly assigned thereto. The beam spots 213 are now incident on the detection regions 215. They impinge centrally on the detection regions 215 in example b), and not centrally but displaced laterally to the right in example c). Nevertheless, it is true in both cases that the beam spots 213 are incident on the respective detection regions 215 in full; thus, the slight positional deviation does not result in any signal loss. It is not necessary to correct the positional deviation in such cases. This would only be involved once a beam spot 213 is incident on more than one detection region 215, in which case a signal which is sufficiently large and exceeds a threshold would be detected accordingly in the adjustment detection region B2.

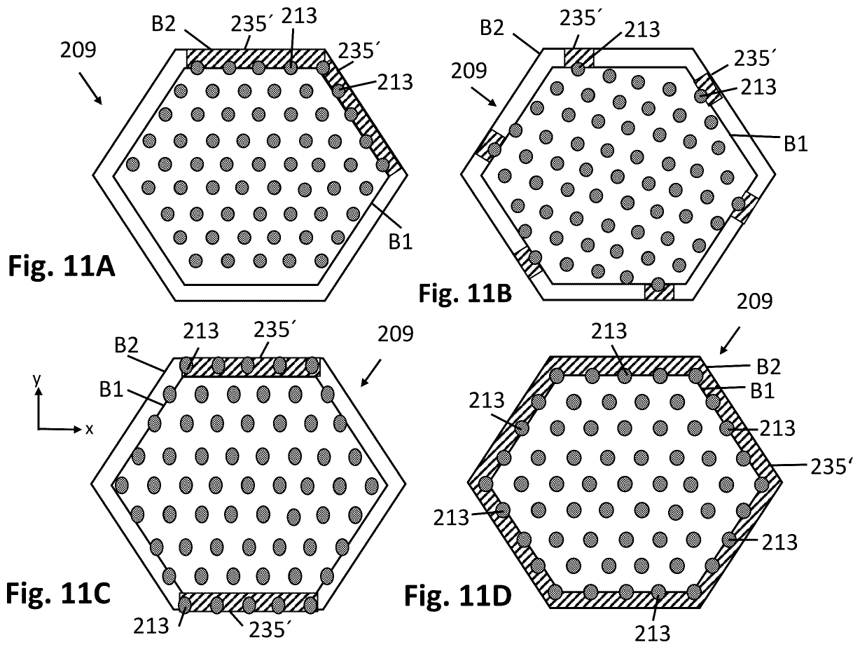

FIGS. 11A-11D schematically show various regions or domains of a detection unit 209 and various positions/positional deviations of second individual particle beams 9 when incident on a detection unit 209. Once again, the image generation detection region B1 and the adjustment detection region B2 are schematically illustrated in FIGS. 11A-11D. The image generation detection region B1 and the adjustment detection region B2 are provided in the same plane. An illustration of the specific subdivision of the regions into detection regions and (additional) detection channels was dispensed with in FIGS. 11A-11D. It can have very different designs, as has already been described in various examples. FIG. 11A) now shows, illustratively, a displacement of the raster of individual particle beams, the raster being represented by the beam spots 213. The hexagon shell-type adjustment detection region B2 exhibits a signal at the top and at an angle to the right; a signal is not detected in the remaining four subregions. Regions where a signal is detected are illustrated with hatching in FIGS. 11A-11D. A positional deviation, which can be corrected in real time still while the image is recorded, can be deduced from this pattern of the obtained signals.

By contrast, FIG. 11B) shows a rotation of the raster: A signal is detected at six points of the adjustment detection region B2 (once again indicated by the hatched regions in the region B2). The corresponding rotation can be corrected in real time by controlling a fast detection position adjustment mechanism.

FIG. 11C) shows anamorphic imaging or an anamorphic positional deviation: The raster of the individual particle beams is enlarged in the y-direction while this is not the case in the x-direction. Accordingly, the signal is detected in two subregions of the adjustment detection region B2 (upper edge and lower edge of the hexagon shell). This can be used to generate a correction signal which can be used to control a fast detection position adjustment mechanism in order to correct, in real time, the position of the second individual particle beams 9 when incident on the detection unit 209.

FIG. 11D) shows a magnification in two directions (x-direction and y-direction) of the raster of the second individual particle beams when incident on the detection unit 209. Therefore, overall, a signal is detected on all six sides of the adjustment detection region D2. Suitable algorithms can use this to generate a control or correction signal, or a corresponding set of such signals, and the positional deviation can be corrected in real time by controlling a fast detection position adjustment mechanism.

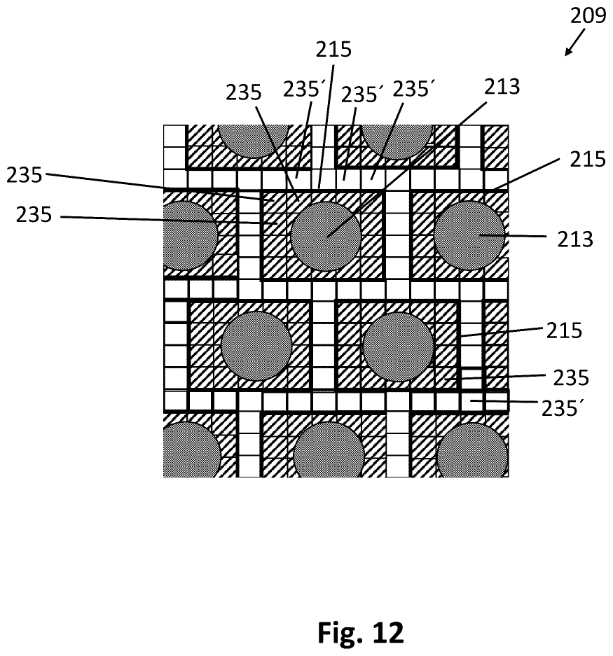

FIG. 12 schematically shows a detection unit 209 with detection regions 215 which are fixedly assigned a plurality of detection channels 235, and with additional detection channels 235′ for detecting a positional deviation when second individual particle beams 9 are incident on the detection unit 209. The fixedly assigned detection channels 235 and the additional detection channels 235′ are provided in the same plane. FIG. 12 is an example of a pixelated detection unit 209 or a sectored detection unit 209. In the example shown, 12 detection channels 235 are in each case fixedly assigned to a detection region 215. In the case of correct positioning, the beam spots 213 are each incident on the detection unit 209 completely within a detection region 215. In this case, a signal is not necessarily detected in each of the detection channels 235 which are fixedly assigned to a detection region 215. Mutually offset row and column portions of additional detection channels 235′ are provided in addition to the detection channels 235 which are fixedly assigned to a detection region 215. In the example shown, the image generation detection region is not path-connected; instead, the individual detection regions 215 are embedded like islands in the adjustment detection region with the additional detection channels 235′. A positional deviation and also the type of positional deviation can be deduced for the ensemble of second individual particle beams 9 and/or for each individual second individual particle beam 9, depending on the additional detection channels 235′ in which a signal is detected.

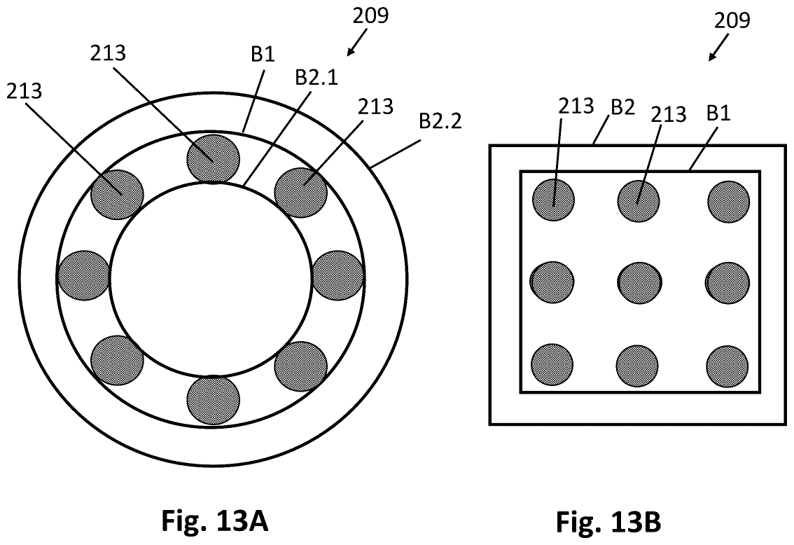

FIGS. 13A-13B schematically show a subdivision of a detection unit 209 into different regions for the purpose of determining and correcting positional deviations when second individual particle beams 9 are incident on the detection unit 209. In this case, FIG. 13A) illustrates a circle and two surrounding ring structures by way of example: The image generation detection region B1 is situated between the outer annulus and the central ring, with all beam spots 213 being incident on the image generation detection region in the case of an optimal incidence of the second individual particle beams 9 on the detection unit 209. The adjustment detection region B2 is not path-connected and subdivided into the subregions B2.1 and B2.2. The subregions B2.1 and B2.2 can optionally comprise one or more additional detection channels 235′. FIG. 13B) schematically shows a rectangular image generation detection region B1, with nine beam spots 213 being depicted therein in illustrative fashion. Each of these beam spots can be assigned a detection region 215, but the latter is not illustrated in detail in FIGS. 13A-13B. The adjustment detection region B2, in the form of a square shell in the example shown, is situated around the outside of the image generation detection region B1. This adjustment detection region may comprise one or more additional detection channels 235′, but these are not illustrated in detail in FIG. 13B). Quite fundamentally, a deviation of the second individual particle beams from the desired reference position when incident on the detection unit 209 can be detected whenever a signal is detected in the adjustment detection region B2 or B2.1 and/or B2.2. The image generation detection region B1 and the adjustment detection regions B2 or B2.1 and/or B2.2 are provided in the same plane.

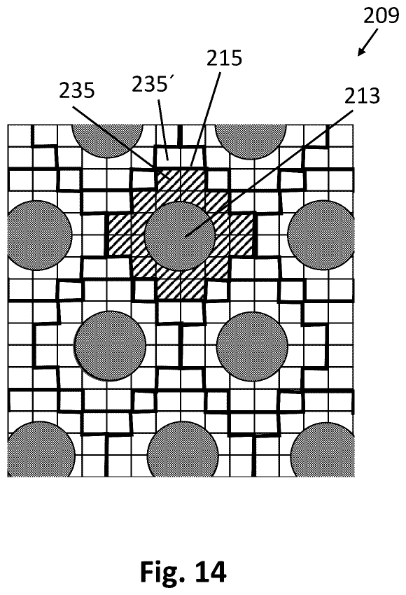

FIG. 14 schematically shows a further detection unit 209 with detection regions 215 which are fixedly assigned a plurality of detection channels 235, and with additional detection channels 235′ for detecting a positional deviation when second individual particle beams 9 are incident on the detection unit 209. The fixedly assigned detection channels 235 and the additional detection channels are provided in the same detection plane. The exemplary embodiment illustrated in FIG. 14 is an example of a slightly more complex assembly or fixed assignment of detection channels 235 to detection regions 215. It is also the case in this example that additional detection channels 235′ for detecting a positional deviation can be formed relatively separated and not in path-connected fashion.

In summary, a method is therefore disclosed for operating a multi-beam particle microscope 1 in an inspection mode of operation, as is an associated multi-beam particle microscope 1. A detection unit 209 comprises an image generation detection region with fixedly assigned detection channels 235 and an adjustment detection region with additional detection channels 235′. The fixedly assigned detection channels 235 and the additional detection channels 235′ are provided in the same detection plane 211. On the basis of signals obtained via the additional detection channels 235′, it is possible to correct an incidence position of the secondary beams 9 on the detection unit 209 in real time, to be precise independently of the specific structure of the detection unit 209.

### LIST OF REFERENCE SIGNS

1 Multi-beam particle microscope
3 Primary particle beams (individual particle beams)
5 Beam spots, incidence locations
7 Object, sample
9 Secondary particle beams
10 Computer system, controller
11 Secondary particle beam path
13 Primary particle beam path
101 Object plane
102 Objective lens
103 Field
200 Detector system
205 Projection lens
207 Scintillator plate
208 Deflector for adjustment purposes
209 Detection system, particle multi-detector, detection unit
211 Detection plane
213 Incidence locations, beam spot of the secondary particles or of the associated photon beam
215 Detection region
217 Field
22 Optical beam path
222 Contrast stop
223 Light optical unit
225 Lens
227 Mirror
229 Lens
231 Lens
235 Detection channel, light receiving surface, signal entrance surface (image generation)
235′ Additional detection channel (position correction)
237 Light detection system
239 Optical fibre, light guide
241 Light detector
243 Region for optical imaging of the scintillator surface
245 Line
300 Beam generating apparatus
301 Particle source
303 Collimation lens system
305 Multi-aperture arrangement
306 Micro-optics
307 Field lens system
309 Diverging particle beam
310 Multi-beam generator
311 Illuminating particle beam
313 Multi-aperture plate
315 Openings in the multi-aperture plate
317 Midpoints of the openings
319 Field
323 Beam foci
325 Intermediate image plane
400 Beam switch
810 Controller for the primary path
820 Controller for the secondary path
830 Adjustment control module
832 Real-time algorithm relating to a positional deviation
833 Detector position adjustment mechanism
840 Image generation control module
842 Image generation algorithms
850 Image display unit
Ef Focal plane
M Centre of the raster of second individual particle beams
V Displacement, positional deviation vector
K Correction vector
D1 Distance between detection regions/detection channels
D2 Distance between detection regions/detection channels
B1 Image generation detection region
B2 Adjustment detection region
S10 Image generation steps
S20 Adjustment steps, readjustment steps for correcting positional deviation
S21 Reading out additional detection channels
S22 Determining whether a positional deviation is present
S23 Determining whether a threshold value is exceeded
S24 Generating correction signal(s)
S25 Controlling fast detector position adjustment mechanism

What is claimed is:

1. A method, comprising:
using a multi-beam particle microscope to irradiate an object with a plurality of charged first individual particle beams, each first individual particle beam irradiating a separate individual field region of the object in a scanning fashion;
collecting second individual particle beams which emanate from the object;
projecting the second individual particle beams onto detection regions of a detection unit so that second individual particle beams emanating from two different individual field regions are projected onto different detection regions, a detection channel or a predetermined plurality of detection channels being fixedly assigned to each detection region;
reading the assigned detection channels and generating individual images of each of the individual field regions based on data obtained via signals from each of the detection regions with their respective assigned detection channel or with their respective assigned detection channels;
reading additional detection channels from the same detection unit, onto which the second individual particle beams are not projected in a targeted fashion and which are not assigned to any detection region, and determining a positional deviation of the second individual particle beams from a reference incidence position when incident on the detection unit based on data obtained via signals from the additional detection channels; and
correcting the positional deviation of the second individual particle beams when incident on the detection unit in real time.

2. The method of claim 1, wherein correcting the positional deviation of the second individual particle beams comprises adjusting the particle optical beam path of the second individual particle beams in real time.

3. The method of claim 1, wherein comprising correcting the positional deviation when generating the individual images.

4. The method of claim 1, further comprising:
classifying the determined positional deviation; and
based on the classification, correcting the positional deviation.

5. The method of claim 1, wherein correcting the positional deviation comprises correcting a global displacement of the second individual particle beams when incident on the detection unit.

6. The method of claim 1, wherein correcting the positional deviation comprises correcting a global rotation of the second individual particle beams when incident on the detection unit.

7. The method of claim 1, wherein correcting the positional deviation comprises correcting a magnification of the second individual particle beams in one direction or in two directions when incident on the detection unit.

8. The method of claim 1, further comprising correcting an individual positional deviation of at least one second individual particle beam when incident on the detection unit in real time.

9. The method of claim 1, comprising correcting the positional deviation only when a threshold value is exceeded.

10. The method of claim 1, wherein the second individual particle beams emanating from the object are generated by the first individual particle beams impinging on the object.

11. One ore more machine-readable hardware storage devices comprising instructions that are executable by one or more processing devices to perform operations comprising the method of claim 1.

12. A system comprising:
one or more processing devices; and
one or more machine-readable hardware storage devices comprising instructions that are executable by one or more processing devices to perform operations comprising the method of claim 1.

13. The system of claim 12, further comprising a multi-beam particle microscope.

14. A multi-beam particle microscope, comprising:
a multi-beam particle source configured to generate a first field of a plurality of charged first individual particle beams;
a first particle optical unit with a first particle optical beam path, the first particle optical unit configured to image the first individual particle beams onto an object plane so that the first individual particle beams impinge an object at incidence locations which define a second field;
a detection unit comprising a plurality of detection regions which define third field, each detection region being fixedly assigned to a detection channel or a plurality of detection channels, the detection unit further comprising additional detection channels which are not assigned to any of the detection regions;
a second particle optical unit with a second particle optical beam path, the second particle optical unit configured to image, in substantially focused fashion, second individual particle beams, which emanate from the incidence locations in the second field, onto the third field of the detection regions of the detection system, the second particle optical unit comprising a fast detection position adjustment mechanism configured to correct a position of the second individual particle beams when incident on the detection unit in real time;
an objective lens configured so that both the first and the second individual particle beams pass through the objective lens;
a beam switch in the first particle optical beam path between the multi-beam particle source and the objective lens, the beam switch in the second particle optical beam path between the objective lens and the detection unit; and
a controller configured to:
control the second particle optical unit;
generate individual images from data obtained via signals from the detection regions with the respective fixedly assigned detection channel or the respective fixedly assigned detection channels;
determine a positional deviation of the second individual particle beams from a reference incidence position when incident on the detection unit from data obtained via signals from the additional detection channels which are not assigned to any of the detection regions, and to generate at least one correction signal serving to correct the positional deviation; and
control the fast detection position adjustment mechanism using the at least one correction signal in real time.

15. The multi-beam particle microscope of claim 14, wherein the detection unit comprises:
an image generation detection region in which all detection regions are arranged; and
an adjustment detection region in which all additional detection channels are arranged.

16. The multi-beam particle microscope of claim 15, wherein the image generation detection region is path-connected, and the adjustment detection region is path-connected.

17. The multi-beam particle microscope of claim 16, wherein:
the adjustment detection region is outside the image generation detection region; or
the image generation detection region is outside the adjustment detection region.

18. The multi-beam particle microscope of claim 15, wherein:
the image generation detection region is not path-connected; and
the adjustment detection region is path-connected but not simply connected.

19. The multi-beam particle microscope of claim 17, wherein each detection region is at least partly surrounded by additional detection channels.

20. The multi-beam particle microscope of claim 14, wherein the additional detection channels are configured so that a positional deviation in the form of a directional deviation of at least one second individual particle beam from its reference incidence position is detectable.

21. The multi-beam particle microscope of claim 14, wherein each detection region comprises exactly one detection channel.

22. The multi-beam particle microscope of claim 14, wherein all detection channels are structurally identical.

23. The multi-beam particle microscope of claim 14, wherein the detection channels fixedly assigned to the detection regions comprise a different structure from the additional detection channels which are not assigned to any of the detection regions.

24. The multi-beam particle microscope of claim 14, wherein each detection channel comprises a signal entrance surface, and the signal entrance surfaces overall are arranged as a hexagon.

25. The multi-beam particle microscope of claim 24, wherein each detection region is fixedly assigned exactly one detection channel, and the additional detection channels not assigned to any detection region are arranged hexagonally around the outside of the detection regions.

26. The multi-beam particle microscope of claim 14, wherein the detection system comprises at least one particle detector.

27. The multi-beam particle microscope of claim 14, wherein the detection system comprises one or more particle detectors and also a plurality of light detectors disposed downstream thereof.

28. The multi-beam particle microscope of claim 27, wherein each detection channel comprises exactly one optical fibre, and different detection channels comprise different optical fibres.

29. The multi-beam particle microscope of claim 27, wherein a detection channel comprises no optical fibre, and the light detection system comprises an array of light-sensitive detectors.

30. The multi-beam particle microscope of claim 14, wherein the fast detection position adjustment mechanism comprises at least one member selected from the group consisting of an electrostatic lens, an electrostatic deflector, an electrostatic stigmator, an air-core coil, and a multi-deflector array.
